(19) United States
(12) Patent Application Publication
(10) Pub. No.: US 2026/0179891 A1
(43) Pub. Date: Jun. 25, 2026

(54) Angle-Actuated Capacitive Sensor for Accurate Angled Deposition or Etch Process Monitoring

(71) Applicant: Applied Materials, Inc., Santa Clara, CA (US)

(72) Inventors: Vikram M. Bhosle, North Reading, MA (US); Joseph C. Olson, Beverly, MA (US); Sage Toko Garrett Doshay, Saratoga, CA (US)

(21) Appl. No.: 18/999,883

(22) Filed: Dec. 23, 2024

(51) Int. Cl. H01J 37/32; H01J 37/244

(52) U.S. Cl. CPC H01J 37/32963; H01J 37/244; H01J 2237/2007; H01J 2237/334

(57) ABSTRACT

A workpiece processing system that creates a ribbon beam at an extraction angle is disclosed. The ribbon beam may include ions, radicals or excited neutrals. The apparatus also includes an angle actuated sensor that is used to measure attributes of the ribbon beam in situ. The angle actuated sensor may be disposed in a location that is aligned with the workpiece so as to be the same distance from the extraction plate as the workpiece, such as on the workpiece holder or on a movable arm. This angle actuated sensor may be rotated so as to measure the amount of particles that are deposited or etched at a plurality of angles. Based on the data collected by the angle actuated sensor, the angle of the beam, the angular spread of the angled beam and the amount of material that is deposited or etched may be determined.

### FIELD

Embodiments of the present disclosure relate to improved monitoring, and more particularly, an apparatus for measuring an amount of material deposited or etched during an angled deposition or etch process.

### BACKGROUND

Fabrication of advanced three-dimensional semiconductor structures with complex surface topology and high packing density presents many technical challenges. As the critical dimension of devices and their pitch decreases, the aspect ratio of features increases.

One technique to fabricate these complex devices is the use of directional processing. In this way, ions, atoms, or molecules may be directed at non-zero angles toward the workpiece to form the desired features. This directional processing may involve deposition, implantation, or etching.

To perform these directional processes, a workpiece processing device may include a blocker disposed near an extraction aperture within the ion source chamber to manipulate the plasma sheath, which in turn controls the angles at which ions exit through the extraction aperture. In this way, the direction of the ions may be controlled.

Of course, directional processing processes may be carried out via other methods. For example, in other embodiments, the workpiece processing device may be used for deposition. In this embodiment, the workpiece processing device may include an ion source chamber with an aperture that directs radicals and excited neutrals toward the workpiece in a predetermined direction.

Further, in some processes, such as certain deposition and etch processes, the angle of the ions may be tightly controlled to achieve the desired patterning.

Therefore, a system and method that allows the angle of the ions, as well as the total amount of material deposited or etched, to be accurately measured in situ would be beneficial. This information may be used to tune the workpiece processing device, resulting in tighter tolerances.

### SUMMARY

A workpiece processing system that creates a ribbon beam at an extraction angle is disclosed. The ribbon beam may include ions, radicals or excited neutrals. The apparatus also includes an angle actuated sensor that is used to measure attributes of the ribbon beam in situ. The angle actuated sensor may be disposed in a location that is aligned with the workpiece so as to be the same distance from the extraction plate as the workpiece. The angle actuated sensor may be disposed on the workpiece holder or on a movable arm. This angle actuated sensor may be rotated so as to measure the amount of material that are deposited or etched at a plurality of angles. Based on the data collected by the angle actuated sensor, the angle of the beam, the angular spread of the angled beam, and the amount of material that is deposited or etched may be determined. This information may be used to determine when to terminate a process, or may be used to validate an installation or maintenance of the apparatus.

According to one embodiment, a workpiece processing apparatus is disclosed. The workpiece processing apparatus comprises a plasma chamber having an extraction aperture to extract an angled beam from a plasma located within the plasma chamber; a workpiece holder, configured to be translated relative to the extraction aperture; and an angle actuated sensor disposed on or within the workpiece holder to measure an attribute of the angled beam at a plurality of different angles. In some embodiments, the angled beam is a ribbon beam. In certain embodiments, the ribbon beam comprises a ribbon ion beam. In certain embodiments, the ribbon beam comprises a ribbon particle beam comprising radicals and excited neutrals. In some embodiments, the ribbon beam has a width and a height, and the angle actuated sensor is disposed along a side of a workpiece in a width direction. In some embodiments, the ribbon beam has a width and a height, and the angle actuated sensor is disposed along a side of a workpiece in a height direction. In some embodiments, the angle actuated sensor rotates about an axis that is parallel to a width direction of the ribbon beam. In some embodiments, the attribute comprises an amount of material deposited or etched by the angled beam. In some embodiments, the attribute comprises an extraction angle of the angled beam. In some embodiments, the attribute comprises an angular spread of the angled beam. In some embodiments, the angle actuated sensor comprises a capacitive sensor. In some embodiments, the capacitive sensor is disposed in a housing, and the housing is pivotally attached to the workpiece holder using a rotating actuator. In certain embodiments, the capacitive sensor is disposed within a collimating column. In some embodiments, at least one additional angle actuated sensor is disposed on or within the workpiece holder, and the angle actuated sensors are disposed at different angles. In some embodiments, the angle actuated sensor is in a plane of a workpiece disposed on the workpiece holder.

According to another embodiment, a workpiece processing apparatus is disclosed. The workpiece processing apparatus comprises a plasma chamber having an extraction aperture to extract an angled beam from a plasma located within the plasma chamber; a workpiece holder, configured to be translated relative to the extraction aperture; a movable arm; and an angle actuated sensor disposed on the movable arm to measure an attribute of the angled beam at a plurality of different angles. In some embodiments, when in a monitoring position, the angle actuated sensor is disposed in a plane of a workpiece disposed on the workpiece holder. In some embodiments, the angle actuated sensor comprises a capacitive sensor disposed in a housing, wherein the housing is pivotally attached to the workpiece holder using a rotating actuator. In certain embodiments, the capacitive sensor is disposed within a collimating column. In some embodiments, the attribute comprises an extraction angle of the angled beam, an angular spread of the angled beam or an amount of material deposited or etched by the angled beam.

### BRIEF DESCRIPTION OF THE FIGURES

For a better understanding of the present disclosure, reference is made to the accompanying drawings, which are incorporated herein by reference and in which:

FIG. 1A is a workpiece processing apparatus in accordance with one embodiment;

FIG. 1B is a workpiece processing apparatus in accordance with a second embodiment;

FIG. 2A-2B show two different positions for the angle actuated sensor;

FIGS. 3A-3B show the angle actuated sensor according to two embodiments; and

FIG. 4 is a workpiece processing apparatus in accordance with another embodiment.

### DETAILED DESCRIPTION

This disclosure describes systems that allow for the measuring of the angle of a beam as it impacts a workpiece. This may be applicable to both etching systems and deposition systems. In some embodiments, this may be a ribbon beam. In the case of etching systems, the ribbon beam may be a ribbon ion beam, while for deposition systems, the ribbon beam may be a ribbon particle beam.

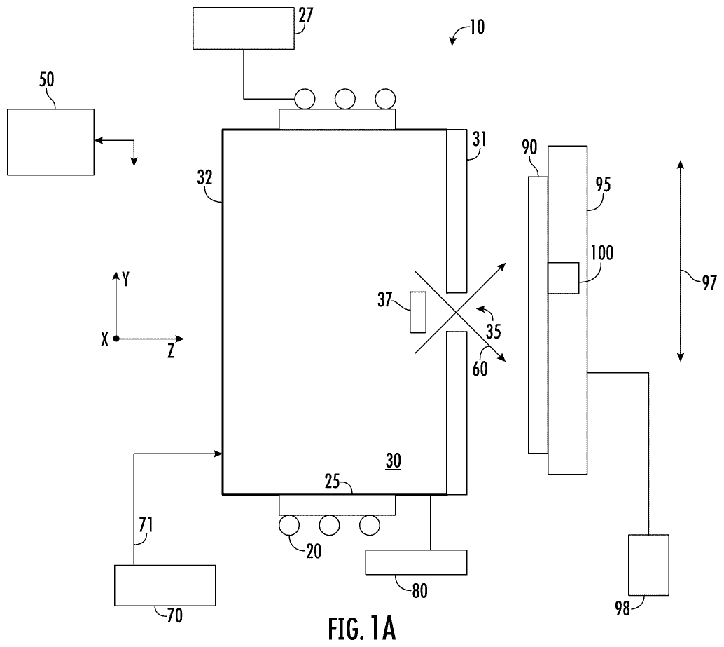

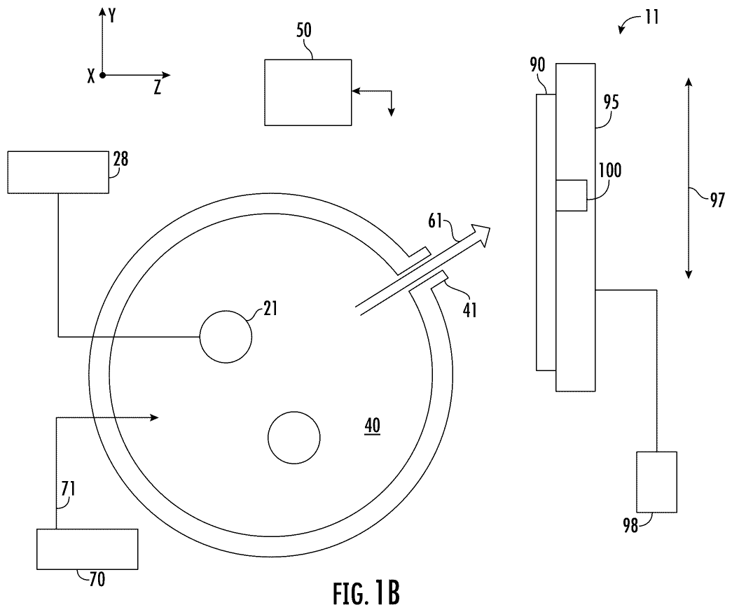

FIG. 1A shows a first embodiment of workpiece processing apparatus 10 for measuring the angle of a ribbon beam directed toward the workpiece 90, and measuring an amount of material that is deposited or etched. In this embodiment, this workpiece processing apparatus 10 may be used for etching processes. The workpiece processing apparatus 10 comprises a plasma chamber 30, which is defined by a plurality of chamber walls 32.

An antenna 20 is disposed external to a plasma chamber 30, proximate a dielectric window 25. The dielectric window 25 may also form one of the walls that define the plasma chamber 30. The antenna 20 is electrically connected to a RF power supply 27, which supplies an alternating voltage to the antenna 20. The voltage may be at a frequency of, for example, 2 MHz or more. While the dielectric window 25 and antenna 20 are shown on opposite sides of the plasma chamber 30, other embodiments are also possible. For example, the antenna 20 may be disposed on the top of the plasma chamber 30. The chamber walls 32 of the plasma chamber 30 may be made of a conductive material, such as graphite. These chamber walls 32 may be biased at an extraction voltage, such as by extraction power supply 80. The extraction voltage may be, for example, 1 kV, although other voltages are within the scope of the disclosure.

The workpiece processing apparatus 10 includes an extraction plate 31 having an extraction aperture 35. The extraction plate 31 may form another wall that defines plasma chamber 30. The extraction aperture 35 may be about 320 mm in the x-direction and 30 mm in the y-direction, although other dimensions are possible. The extraction plate 31 may have a thickness in the z-direction of between 5 and 10 mm, although other dimensions are also possible. This extraction plate 31 may be disposed on the side of the plasma chamber 30 adjacent to the dielectric window 25, although other configurations are also possible. In certain embodiments, the extraction plate 31 may be constructed from an insulating material. For example, the extraction plate 31 may comprise quartz, sapphire, alumina or a similar insulating material. The use of an insulating material may allow modulation of the plasma sheath, which affects the angle at which charged ions exit the extraction aperture 35. In other embodiments, the extraction plate 31 may be constructed of a conducting material.

A blocker 37 may be disposed proximate the extraction aperture 35 on the interior of the plasma chamber 30. In certain embodiments, the blocker 37 is constructed from an insulating material. The blocker 37 may be about 3-5 mm in the z-direction, and the same dimension as the extraction aperture 35 in the x-direction. The length of the blocker 37 in the y-dimension may be varied to achieve the target extraction angles.

The position and size of the blocker 37 along with the size and shape of the edges of the extraction aperture 35 may define the boundary of the plasma sheath within the plasma chamber 30. The boundary of the plasma sheath, in turn, determines the angle at which charged ions cross the plasma sheath and exit through the extraction aperture 35. In certain embodiments, the blocker 37 may include a conductive material. In these embodiments, the conductive material on the blocker 37 may be biased so as to create an electric field proximate the extraction aperture 35. The electric field may also serve to control the angle at which the charged ions exit through the extraction aperture 35. A blocker 37 positioned between the interior of the plasma chamber 30 and the extraction aperture 35, such as is shown in FIG. 1A, may create a bimodal extraction angle profile. In other words, charged ions may exit the extraction aperture 35 at either +θ° or −θ°, where θ is determined by the size and position of the blocker 37, the width of extraction aperture 35 and the electric fields proximate the extraction aperture. Note that extraction angles are measured relative to a line perpendicular to the surface of the workpiece 90. In other words, an extraction angle of 0° indicates that the ions are striking the workpiece at a right angle, while an extraction angle of 90° indicates that the ions are parallel to the surface of the workpiece.

A workpiece 90 is disposed proximate and outside the extraction plate 31 of the plasma chamber 30. In some embodiments, the workpiece 90 may be within about 1 cm of the extraction plate 31 in the z-direction, although other distances are also possible. In operation, the antenna 20 is powered using a RF signal from the RF power supply 27 so as to inductively couple energy into the plasma chamber 30. This inductively coupled energy excites the feed gas introduced from a gas storage container 70 via gas inlet 71, thus generating a plasma. While FIG. 1A shows an antenna 20 and an RF power supply 27, other plasma generators may also be used with the present disclosure. For example, a capacitively coupled plasma generator may be used.

A controller 50 may be in communication with one or more of the power supplies, such as extraction power supply 80, RF power supply 27, and bias power supply 98, such that the voltage or current supplied by these power supplies may be monitored and/or modified. The controller 50 may include a processing unit, such as a microcontroller, a personal computer, a special purpose controller, or another suitable processing unit. The controller 50 may also include a non-transitory storage element, such as a semiconductor memory, a magnetic memory, or another suitable memory. This non-transitory storage element may contain instructions and other data that allows the controller 50 to perform the functions described herein.

The plasma within the plasma chamber 30 may be biased at the voltage being applied to the chamber walls 32 by the extraction power supply 80. The workpiece 90, which may be disposed on a workpiece holder 95, is disposed outside the plasma chamber 30 and proximate the extraction plate 31. The workpiece holder 95 may be electrically biased by a bias power supply 98. The difference in potential between the plasma and the workpiece 90 causes charged ions in the plasma to be accelerated through the extraction aperture 35 in the form of one or more ribbon ion beams and toward the workpiece 90. In other words, positive ions are attracted toward the workpiece 90 when the voltage applied by the extraction power supply 80 is more positive than the bias voltage applied by the bias power supply 98. Thus, to extract positive ions, the chamber walls 32 may be biased at a positive voltage, while the workpiece 90 is biased at a less positive voltage, ground or a negative voltage. In other embodiments, the chamber walls 32 may be grounded, while the workpiece 90 is biased at a negative voltage. In yet other embodiments, the chamber walls 32 may be biased at a negative voltage, while the workpiece 90 is biased at a more negative voltage.

The ribbon ion beam 60 may be at least as wide as the workpiece 90 in one direction, such as the x-direction, and may be much narrower than the workpiece 90 in the orthogonal direction (or y-direction). In one embodiment, the extracted ribbon ion beam 60 may be about 1 mm in the y-direction and 320 mm in the x-direction.

Further, the workpiece holder 95 and workpiece 90 may be translated in the direction of travel 97 relative to the extraction aperture 35 such that different portions of the workpiece 90 are exposed to the ribbon ion beam 60. The process wherein the workpiece 90 is translated so that the workpiece 90 is exposed to the ribbon ion beam 60 is referred to as “a pass”. A pass may be performed by translating the workpiece holder 95 and workpiece 90 while maintaining the position of the plasma chamber 30. The speed at which the workpiece 90 is translated relative to the extraction aperture 35 may be referred to as workpiece scan velocity. In certain embodiments, the workpiece scan velocity may be about 100 mm/sec, although other speeds may be used. In another embodiment, the plasma chamber 30 may be translated while the workpiece 90 remains stationary. In other embodiments, both the plasma chamber 30 and the workpiece 90 may be translated. In some embodiments, the workpiece 90 moves at a constant workpiece scan velocity relative to the extraction aperture 35 in the y-direction, so that the entirety of the workpiece 90 is exposed to the ribbon ion beam 60 for the same amount of time.

As described above, the extraction aperture 35 is used to direct the charged ions toward the workpiece 90 at a predetermined angle.

FIG. 1B shows a different workpiece processing apparatus 11 that may be used for the deposition of material.

The workpiece processing apparatus 11 includes a plasma chamber 40. While FIG. 1B shows the plasma chamber 40 to be cylindrical in shape, it is understood that the plasma chamber 40 may have other shapes. Like the workpiece processing system of FIG. 1A, the plasma chamber 40 may be in communication with a gas storage container 70 via a gas inlet 71. Within the plasma chamber 40 may be one or more antennas 21, which are in communication with a RF power supply 28, which supplies an alternating voltage to the one or more antennas 21. The voltage may be at a frequency of, for example, 2 MHz or more. The RF power supply 28 is used to energize the one or more antennas 21, creating a plasma rich with ions, radicals and excited neutrals. The plasma chamber 40 includes an extraction aperture 41. In some embodiments, the extraction aperture 41 may be much larger in the width direction (along the length of the cylinder) than the height direction (along the circumferential direction). For example, the extraction aperture 41 may have a width that is greater than a diameter of the workpiece 90. In some embodiments, the extraction aperture 41 may protrude radially from the plasma chamber 40 to better collimate the extracted particles.

In some embodiments, the pressure within the plasma chamber 40 is greater than that outside the plasma chamber 40. This pressure differential causes the flow of particles from the plasma chamber 40 toward the workpiece 90. This flow may be in the form of a ribbon particle beam 61. The extraction aperture 41 may be constructed to collimate the extracted particles. The extraction aperture 41 may also serve to neutralize any ions such that the majority of the extracted particles are radicals and excited neutrals.

As described above with respect to FIG. 1A, the workpiece processing apparatus 11 also includes a controller 50 to perform the functions described herein. The workpiece processing apparatus 11 also includes a workpiece holder 95, which is disposed outside the plasma chamber 40 and proximate the extraction aperture 41.

Further, as explained above, the workpiece holder 95 and workpiece 90 may be translated in the direction of travel 97 relative to the extraction aperture 41 such that different portions of the workpiece 90 are exposed to the ribbon particle beam 61. A pass may be performed by translating the workpiece holder 95 and workpiece 90 while maintaining the position of the plasma chamber 40. In certain embodiments, the workpiece scan velocity may be about 100 mm/sec, although other speeds may be used. In another embodiment, the plasma chamber 40 may be translated while the workpiece 90 remains stationary. In other embodiments, both the plasma chamber 40 and the workpiece 90 may be translated. In some embodiments, the workpiece 90 moves at a constant workpiece scan velocity relative to the extraction aperture 41 in the y-direction, so that the entirety of the workpiece 90 is exposed to the ribbon particle beam 61 for the same amount of time. In some embodiments, bias power supply 98 may be omitted.

In both embodiments, precise measurement of the angle of the ribbon beam may be desirable, wherein the ribbon beam may be a ribbon ion beam 60 or a ribbon particle beam 61. Therefore, in some embodiments, the present systems include an angle actuated sensor 100 that is disposed on or within the workpiece holder 95. The workpiece holder 95 is larger than the workpiece 90 in two orthogonal directions, the width or X direction (which is parallel to the longer dimension of the ribbon beam) and in the height or Y direction (which is parallel to the shorter dimension of the ribbon beam and also parallel to the direction of travel 97 of the workpiece holder 95).

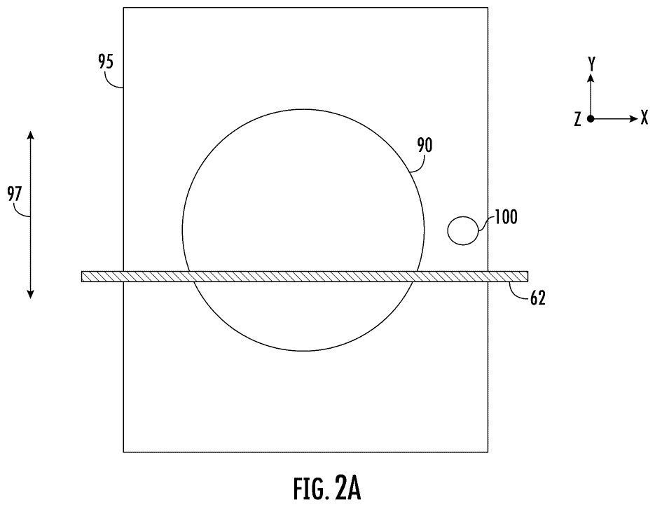

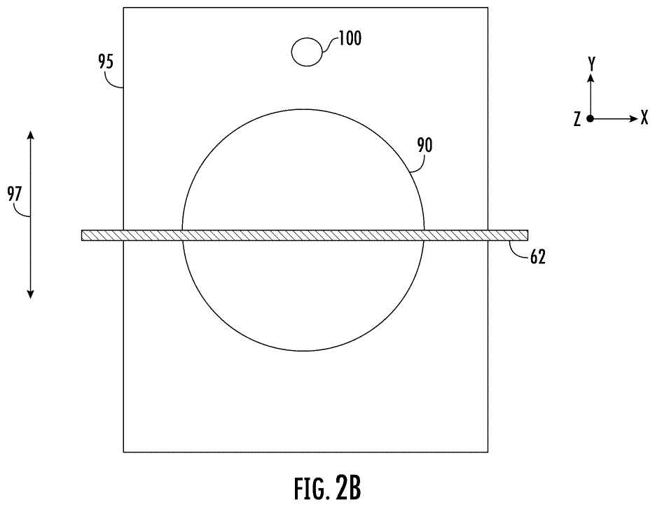

As shown in FIG. 2A, this angle actuated sensor 100 may be disposed on or within the workpiece holder 95 on the side of the workpiece 90 in the width direction, such that the angle actuated sensor 100 is exposed to the ribbon beam 62 at the same time as a portion of the workpiece 90. Alternatively, as shown in FIG. 2B, this angle actuated sensor 100 may be disposed on or within the workpiece holder 95 on the side of the workpiece 90 in the height direction, such that the angle actuated sensor 100 is exposed to the ribbon beam 62 as a result of the movement of the workpiece holder 95 during each pass.

In certain embodiments, the angle actuated sensor 100 may be disposed in a cavity in the workpiece holder 95 so that the surface of the sensor is aligned with the top surface of the workpiece 90.

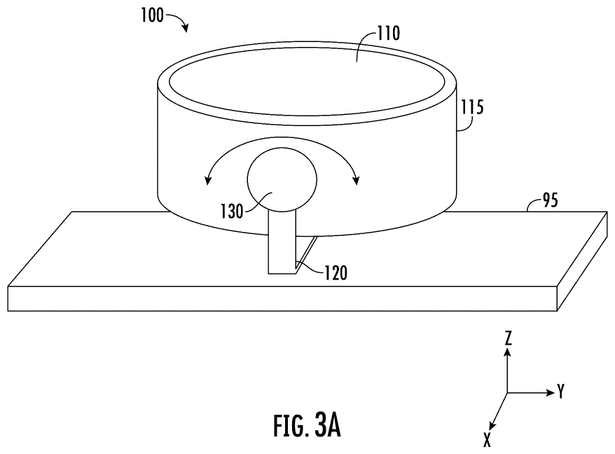

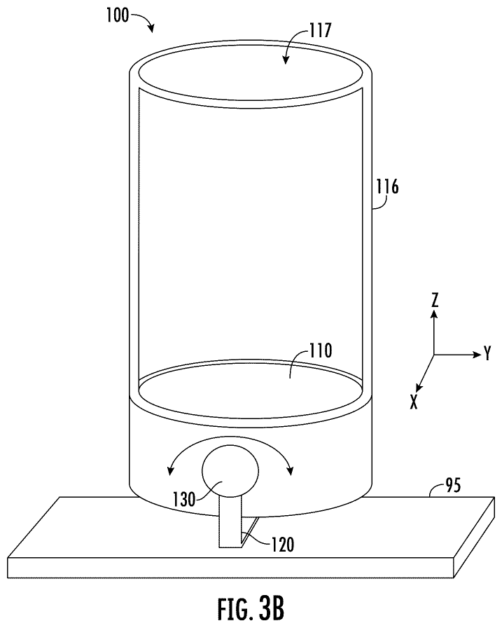

FIGS. 3A-3B show two different embodiments of an angle actuated sensor 100. In FIG. 3A, the angle actuated sensor 100 comprises a capacitive sensor 110 disposed on or near the top surface of a housing 115. The capacitive sensor 110 measures the capacitance on the surface of the capacitive sensor 110 and converts that capacitance to a voltage or current, which is proportional to the thickness of the material that is disposed on the surface of the capacitive sensor 110. In some embodiments, the sensor may be able to measure to resolutions and accuracies of 100 aF or smaller. The output from the angle actuated sensor 100 may be provided to the controller 50. In some embodiments, the capacitive sensor 110 may comprise a plurality of electrodes disposed on or near the surface, wherein the capacitance between the electrodes is measured. The housing 115 may be rotatably connected to the workpiece holder 95, such as via a bracket 120, which is affixed to the workpiece holder 95. A rotating actuator 130 may be used to rotate the housing 115. The rotating actuator 130 may be a stepper motor or a traditional motor. The angle actuated sensor 100 is disposed on or within the workpiece holder 95 such that the housing 115 may rotate about an axis that is parallel to the X or width direction of the ribbon beam 62.

FIG. 3B shows a second embodiment of an angle actuated sensor 100. This embodiment includes the capacitive sensor 110, the bracket 120 affixed to the workpiece holder 95 and the rotating actuator 130 that were described with respect to FIG. 3A. However, in this embodiment, the housing 116 is elongated and forms a hollow tube 117. The capacitive sensor 110 is disposed within the hollow tube 117, such as at the bottom of the hollow tube 117. In this embodiment, only those ions and particles that travel in a direction that is substantially parallel to the central axis of the hollow tube 117 reach the capacitive sensor 110. In this way, the housing 116 serves as a collimating column.

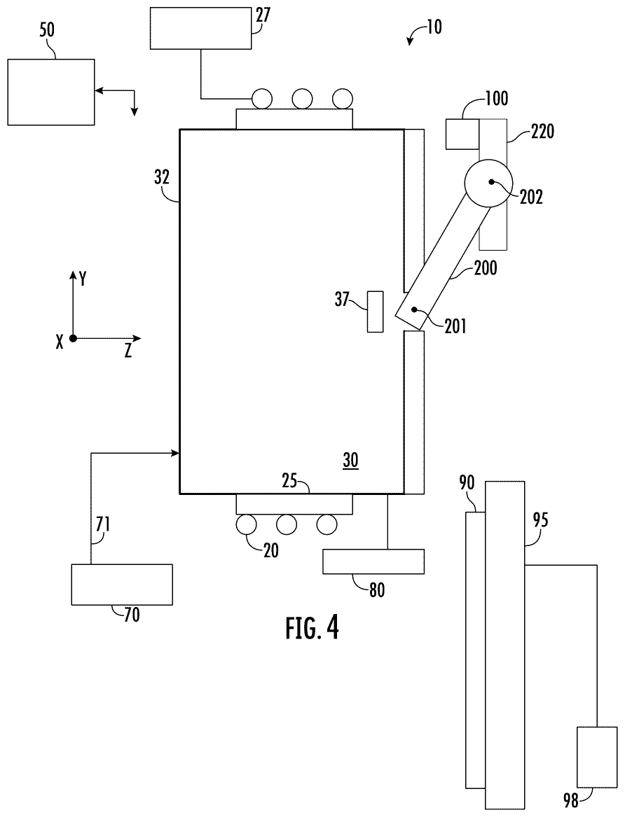

While FIG. 2A-2B show the angle actuated sensor 100 mounted on or within the workpiece holder 95, other embodiments are also possible. One such embodiment is shown in FIG. 4. The workpiece processing apparatus 10 is as described above with respect to FIG. 1A. Note that this configuration is also applicable to the workpiece processing system shown in FIG. 1B. Some reference designators have been removed for clarity. The angle actuated sensor 100 may be mounted on a movable arm 200. This movable arm 200 may be pivotable about one or more axis. For example, as shown in FIG. 4, the movable arm 200 may be mounted to a point 201 that may be aligned with the extraction aperture 35 in the width direction. The movable arm 200 may include a second pivot point 202, such that the bracket 220 on which the angle actuated sensor 100 is disposed can rotate.

In some embodiments, the movable arm 200 may be moved to an inactive position where it does not interfere with the movement of the workpiece holder 95 when not in use. When in use, the workpiece holder 95 may be moved to a monitoring position so that the angle actuated sensor 100 is placed in the path of the ribbon beam at a position that is aligned with the workpiece holder 95 in the Z direction.

In another embodiment, the bracket 220 that holds the angle actuated sensor 100 may be sufficiently thin in the X direction such that it may be placed in the path of the ribbon beam without interfering with the workpiece holder 95. For example, the bracket 220 may be positioned next to the workpiece holder 95 in the width or X direction. In this embodiment, the angle actuated sensor 100 may remain stationary while the workpiece holder 95 is translated along the direction of travel 97.

Furthermore, note that the movable arm 200 may be mounted at other locations. For example, the movable arm 200 may be mounted to a wall located behind or adjacent to the workpiece holder 95 or to the workpiece holder 95 itself. Either of the embodiments described above are also possible if the movable arm 200 is mounted in this other location.

Thus, in the embodiments shown in FIGS. 1A-1B, 2A-2B and 4, it is possible to dispose the angle actuated sensor 100 in the plane of the workpiece 90 so as to determine the characteristics of the ribbon beam at the distance from the extraction aperture where they impact the workpiece 90. The term “in the plane” denotes that the capacitive sensor is a distance from the extraction aperture that is within 10 mm of the distance that the workpiece 90 is from the extraction aperture. In certain embodiments, the capacitive sensor is a distance from the extraction aperture that is within 5 mm of the distance that the workpiece 90 is from the extraction aperture. In certain embodiments, the difference in these distances is less than 2 mm.

When ribbon beams are extracted from the extraction aperture, the beamlets do not all have the same extraction angle. There is typically a central angle, which is referred to as the extraction angle, and a distribution of angles around this central angle. This distribution of angles around the extraction angle is referred to as beam spread. The following describes several methods that may be used to measure the extraction angle and optionally the beam spread.

A first method uses the angle actuated sensor shown in FIG. 3A. The angle actuated sensor 100 may be disposed in the path of the ribbon beam. This may be done by proper positioning of the workpiece holder 95, if the embodiment of FIGS. 1A-1B is used, or proper positioning of the movable arm 200 if the embodiment of FIG. 4 is used. The angle actuated sensor 100 is then rotated through a wide range of angles. At each of a plurality of rotational angles, the capacitance measured by the angle actuated sensor 100 is provided to the controller 50. This plurality of measurements is then used by the controller 50 to determine the central extraction angle and the spread.

A second method uses the angle actuated sensor shown in FIG. 3B. The angle actuated sensor 100 in this embodiment only collects material that are travelling along a narrow range of angles. Thus, the angle actuated sensor 100 is set to a first rotational position, and passed through the ribbon beam, where a measurement is made. Before each pass or plurality of passes, the rotational angle of the angle actuated sensor 100 is varied slightly. In this way, the data received by the controller 50 during that pass or plurality of passes represents the change in capacitance associated with each discrete angle. Multiple passes at different rotational angles are performed to provide data at a plurality of different discrete angles. Using this data, the rotational angle with the maximum change in capacitance may be defined as the extraction angle. The spread may be calculated based on the material collected for the rotational angles on either side of the extraction angle.

In addition to determining the angle at which the beam is focused, the angle actuated sensor 100 has other functions. For example, in the case of a deposition process, such as one using the workpiece processing apparatus of FIG. 1B, the angle actuated sensor 100 may be used to determine when an appropriate or desired amount of material has been deposited at the desired angle. In this embodiment, the angle actuated sensor 100 is disposed at the extraction angle of the ribbon particle beam. This may be a known value, or may be determined using the techniques described above. Before the deposition process begins, the controller 50 may obtain the current capacitance value from the angle actuated sensor 100. The deposition process may then begin. After some interval, which may be measured as an amount of time or a number of passes, the controller 50 again obtains the capacitance value from the angle actuated sensor 100. Using the initial capacitance value and the current capacitance value, the controller 50 may determine the thickness of the material that has been deposited on the surface of the sensor. Once the desired thickness of material is detected, the controller 50 may terminate the deposition process.

Likewise, the angle actuated sensor may also be used for etching processes. In one embodiment, material is intentionally deposited on the surface of the angle actuated sensor prior to the etching process. As described above, an initial capacitance value may be obtained. As the etching process is ongoing, the etching ions will remove material from the surface of the angle actuated sensor, decreasing the measured capacitance. The controller may then obtain a capacitance value during each interval, which may be in terms of time or number of passes, until the desired amount of material has been removed from the surface of the sensor. Alternatively, many etching processes utilize chemistries that both deposit material and etch material. The balance between these two species may result in a directional etch with a sidewall deposition. Thus, the sensor may be able to monitor the net change in material deposited due to the concurrent etching and deposition processes.

In another embodiment, a plurality of angle actuated sensors may be employed. These sensors may be disposed at different angles. As an example, if an odd number of sensors are used, one may be actuated to the extraction angle. Half of the remaining sensors may be actuated at angles that are smaller than the extraction angle, while the second half may be actuated at angles that are greater than the extraction angle. For example, if the expected extraction angle is θ° and 5 sensors are used, the sensors may be actuated to be at angles θ−10°, θ−5°, θ°, θ+5° and θ+10°, as an example. In this way, the angular spread may be measured, as well as the amount of material being deposited or etched at these different angles.

While the figures and disclosure describes a ribbon beam, it is understood that the angle actuated sensor may be employed in workpiece processing systems that utilize a spot beam as well.

The embodiments described above in the present application may have many advantages.

For example, this system may be used to monitor processes in situ in real time. For example, the angle actuated sensor 100 may be exposed to the ribbon beam during each pass of the workpiece holder 95. Based on the amount of material detected, the controller 50 may terminate the etching or deposition process. In this way, the thickness of the deposition or the depth of the etching process may be more tightly controlled. In this embodiment, the angle actuated sensor 100 may be rotated to be at the angle at which the ribbon beam is impacting the workpiece 90. During each pass, the angle actuated sensor 100 is impacted by the ribbon beam. Using the change in capacitance detected by the angle actuated sensor 100, the controller 50 may determine the amount of material that is etched or deposited during each pass, and may more accurately terminate the process.

Another use case involves chamber matching when installing a workpiece processing apparatus, which may be a new system, a system after it has undergone a preventative maintenance (PM) process, or a system that has undergone unexpected downtime. Using the angle actuated sensor 100, oriented at the desired extraction angle, extremely precise monitoring of quasi-on-wafer results may be gathered quickly during the deposition or etch process. This may save significant time and expense as compared to the traditional method of processing metrology wafers, performing metrology on them, analyzing the data, and then determining if any of the results are outside the specifications. In this way, if any aspect of the (re)installation is carried out incorrectly, the angle actuated sensor 100 would enable immediate feedback that the system is not performing as expected/desired. As an example, the angle actuated sensor 100 may detect that the extraction angle or the angled etch or deposition rate is different from that which is desired.

Another use case involves monitoring the workpiece processing system over time. Etch and deposition processes tend to drift over time as, for example, material builds up on the walls of the chamber from deposition. Periodic monitoring of the extraction angle, angular spread and angled etch and deposition rates may help determine when a PM process may be warranted.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A workpiece processing apparatus, comprising:
a plasma chamber having an extraction aperture to extract an angled beam from a plasma located within the plasma chamber;
a workpiece holder, configured to be translated relative to the extraction aperture; and
an angle actuated sensor disposed on or within the workpiece holder to measure an attribute of the angled beam at a plurality of different angles.

2. The workpiece processing apparatus of claim 1, wherein the angled beam is a ribbon beam.

3. The workpiece processing apparatus of claim 2, wherein the ribbon beam comprises a ribbon ion beam.

4. The workpiece processing apparatus of claim 2, wherein the ribbon beam comprises a ribbon particle beam comprising radicals and excited neutrals.

5. The workpiece processing apparatus of claim 2, wherein the ribbon beam has a width and a height, and wherein the angle actuated sensor is disposed along a side of a workpiece in a width direction.

6. The workpiece processing apparatus of claim 2, wherein the ribbon beam has a width and a height, and wherein the angle actuated sensor is disposed along a side of a workpiece in a height direction.

7. The workpiece processing apparatus of claim 2, wherein the angle actuated sensor rotates about an axis that is parallel to a width direction of the ribbon beam.

8. The workpiece processing apparatus of claim 1, wherein the attribute comprises an amount of material deposited or etched by the angled beam.

9. The workpiece processing apparatus of claim 1, wherein the attribute comprises an extraction angle of the angled beam.

10. The workpiece processing apparatus of claim 1, wherein the attribute comprises an angular spread of the angled beam.

11. The workpiece processing apparatus of claim 1, wherein the angle actuated sensor comprises a capacitive sensor.

12. The workpiece processing apparatus of claim 11, wherein the capacitive sensor is disposed in a housing, wherein the housing is pivotally attached to the workpiece holder using a rotating actuator.

13. The workpiece processing apparatus of claim 12, wherein the capacitive sensor is disposed within a collimating column.

14. The workpiece processing apparatus of claim 1, further comprising at least one additional angle actuated sensor disposed on or within the workpiece holder, wherein the angle actuated sensors are disposed at different angles.

15. The workpiece processing apparatus of claim 1, wherein the angle actuated sensor is in a plane of a workpiece disposed on the workpiece holder.

16. A workpiece processing apparatus, comprising:
a plasma chamber having an extraction aperture to extract an angled beam from a plasma located within the plasma chamber;
a workpiece holder, configured to be translated relative to the extraction aperture;
a movable arm; and
an angle actuated sensor disposed on the movable arm to measure an attribute of the angled beam at a plurality of different angles.

17. The workpiece processing apparatus of claim 16, wherein, when in a monitoring position, the angle actuated sensor is disposed in a plane of a workpiece disposed on the workpiece holder.

18. The workpiece processing apparatus of claim 16, wherein the angle actuated sensor comprises a capacitive sensor disposed in a housing, wherein the housing is pivotally attached to the workpiece holder using a rotating actuator.

19. The workpiece processing apparatus of claim 18, wherein the capacitive sensor is disposed within a collimating column.

20. The workpiece processing apparatus of claim 16, wherein the attribute comprises an extraction angle of the angled beam, an angular spread of the angled beam or an amount of material deposited or etched by the angled beam.
